(19) United States
(12) Patent Application Publication
(10) Pub. No.: US 2013/0109132 A1
(43) Pub. Date: May 2, 2013

(54) BACK CONTACT THROUGH-HOLES FORMATION PROCESS FOR SOLAR CELL FABRICATION

(71) Applicants: Michael P. Stewart, San Francisco, CA (US); Jeffrey L. Franklin, Albuquerque, NM (US)

(72) Inventors: Michael P. Stewart, San Francisco, CA (US); Jeffrey L. Franklin, Albuquerque, NM (US)

(21) Appl. No.: 13/647,962

(22) Filed: Oct. 9, 2012

Related U.S. Application Data
(60) Provisional application No. 61/552,752, filed on Oct. 28, 2011.

(51) Int. Cl. H01L 31/18

(52) U.S. Cl. 438/98; 438/57; 257/E31.124

(57) ABSTRACT

Embodiments of the invention contemplate the formation of a high efficiency solar cell using a laser patterning process to form openings in a passivation layer on a surface of a solar cell substrate. In one embodiment, a method of forming an opening in a passivation layer on a solar cell substrate includes forming a passivation layer on a back surface of a substrate, the substrate having a first type of doping atom on the back surface of the substrate and a second type of doping atom on a front surface of the substrate, and providing a series of laser pulses to the passivation layer for between about 500 picoseconds and about 80 nanoseconds to form openings in the passivation layer.

### CROSS-REFERENCE TO RELATED APPLICATIONS

This application claims benefit of U.S. Provisional Application Ser. No. 61/552,752 filed Oct. 28, 2011 (Attorney Docket No. APPM/16388L), which is incorporated by reference in its entirety.

### BACKGROUND OF THE INVENTION

1. Field of the Invention

Embodiments of the invention generally relate to the fabrication of back contact through-holes in a passivation layer of photovoltaic cells, more particularly, fabrication of back contact through-holes in a passivation layer on a back surface of photovoltaic cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost required to form solar cells.

There are various approaches for fabricating the active regions and the current carrying metal lines, or conductors, of the solar cells. Manufacturing high efficiency solar cells at low cost is the key for making solar cells more competitive for the generation of electricity for mass consumption. The efficiency of solar cells is directly related to the ability of a cell to collect charges generated from absorbed photons in the various layers. A good passivation layer can provide a desired film property that reduces recombination of the electrons or holes in the solar cells and redirects electrons and charges back into the solar cells to generate photocurrent. When electrons and holes recombine, the incident solar energy is re-emitted as heat or light, thereby lowering the conversion efficiency of the solar cells.

FIG. 1 depicts a cross sectional view of a conventional crystalline silicon type solar cell substrate, or substrate 110 that may have a passivation layer 104 formed on a surface, e.g. a back surface 125, of the substrate 110. A silicon solar cell 100 is fabricated on the crystalline silicon type solar cell substrate 110 having a textured surface 112. The substrate 110 includes a p-type base region 121, an n-type emitter region 122, and a p-n junction region 123 disposed therebetween. The p-n junction region 123 is formed between the p-type base region 121 and the n-type emitter region 122 to form a heterojunction type solar cell 100. The electrical current generates when light strikes a front surface 120 of the substrate 110. The generated electrical current flows through metal front contacts 108 and metal backside contacts 106 formed on a back surface 125 of the substrate 110.

A passivation layer 104 may be disposed between the back contact 106 and the p-type base region 121 on the back surface 125 of the solar cell 100. The passivation layer 104 may be a dielectric layer providing good interface properties that reduce the recombination of the electrons and holes, drives and/or diffuses electrons and charge carriers back to the junction region 123, and minimize light absorption. The passivation layer 104 is drilled and/or patterned to form openings 109 (e.g., back contact through-holes) that allow a portion 107, e.g., fingers, of the back contact 106 extending through the passivation layer 104 to be in electrical contact/communication with the p-type base region 121. The plurality of fingers 107 may be formed in the passivation layer 104 that are electrically connected to the back contact 106 to facilitate electrical flow between the back contact 106 and the p-type base region 121. Generally, the back contact 106 is formed in the passivation layer 104 by a metal paste process, pasting metal into the openings 109 formed in the passivation layer 104. However, when pasting the metal fingers 107 of the back contact 106 into the openings 109 formed in the passivation layer 104, the aggressive etchants contained in the metal paste may undesirably etch and attack the passivation layer 104 adjacent to the openings 109, thereby deteriorating the film properties of the passivation layer 104. FIG. 2 depicts an enlarged view 150 of the fingers 107 formed in the openings 109 of the passivation layer 104 disposed between the back contact 106 and the p-type base region 121. It is noted that the substrate 110 depicted in FIG. 2 is flipped over and up side down for ease of explanation of the openings 109 formed in the passivation layer 104. The etchant from the metal paste may attack the sidewalls 204 of the openings 109 formed in the passivation layer 104, forming undesired cracks, pits, or voids around the openings 109 in the passivation layer 104, thereby resulting metal paste leaking into undesired areas in the passivation layer 104 and eventually leading to circuit shortage or device failure.

Therefore, there exists a need for improved methods and apparatus to form a metal contact into a passivation layer while maintaining good passivation layer film properties.

### SUMMARY OF THE INVENTION

Embodiments of the invention contemplate the formation of a high efficiency solar cell utilizing a laser patterning process to form openings in a passivation layer while maintaining good film properties of the passivation layer on a surface of a solar cell substrate. In one embodiment, a method of forming an opening in a passivation layer on a solar cell substrate includes forming a passivation layer on a back surface of a substrate, the substrate having a first type of doping atom on the back surface of the substrate and a second type of doping atom on a front surface of the substrate, and providing a series of laser pulses to the passivation layer for between about 80 nancoseconds and about 500 picoseconds to form openings in the passivation layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts a schematic cross-sectional view of a conventional solar cell having a passivation layer and back metal contact formed on a back surface of a substrate;

FIG. 2 depicts a enlarged view of the passivation layer disposed on the substrate of FIG. 1;

FIG. 3 depicts a diagram of a side view of one embodiment of a laser patterning apparatus that may be utilized to practice the present invention;

FIG. 4 depicts a flow diagram of a method to perform a laser patterning process on a passivation layer of a solar cell according to embodiments of the invention;

FIG. 5A depicts a cross sectional view of a passivation layer formed on a substrate after a laser patterning process thereon in accordance with the method of FIG. 4;

FIG. 5B depicts a top view of a passivation layer formed on a substrate after a laser patterning process thereon in accordance with the method of FIG. 4; and

FIG. 5C depicts a cross sectional view of a metal layer filing into a patterened passivation layer formed on a substrate after a laser patterning process thereon in accordance with the method of FIG. 4.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention contemplate the formation of through-holes formed in a passivation layer and back metal contact filling in the through-holes maintaining high passivation layer film qualities so as to form a high efficiency solar cell device. In one embodiment, the method utilizes a laser patterning process to form through-holes (e.g., openings) in a passivation layer on a surface of a solar cell substrate. The laser patterning process may form openings in the passivation layer while maintaining desired film properties of an interface formed adjacent to the openings in contact with the back metal contact.

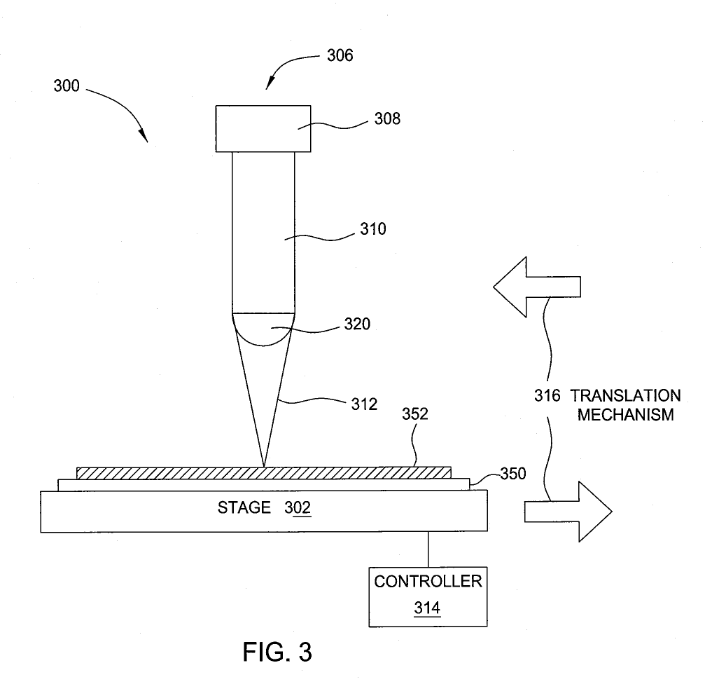

FIG. 3 depicts a laser patterning apparatus 300 that may be used to remove film materials from a material layer to form openings in the material layer disposed on a substrate. In one embodiment, the laser patterning apparatus 300 comprises a laser module 306, a stage 302 configured to receive a substrate 350 disposed thereon, and a translation mechanism 316 configured to control the movement of the stage 302. The laser module 306 comprises a laser radiation source 308 and a focusing optical module 310 disposed between the laser radiation source 308 and the stage 302.

In one embodiment, the laser radiation source 308 may be a light source made from Nd:YAG, Nd:YVO₄, crystalline disk, fiber-Diode and other sources that can provide and emit a continuous wave of radiation at a wavelength between about 180 nm and about 1064 nm, such as about 355 nm. In another embodiment, the laser radiation source 308 may include multiple laser diodes, each of which produces uniform and spatially coherent light at the same wavelength. In yet another embodiment, the power of the laser diode/s is in the range of about 5 Watts to 15 Watts.

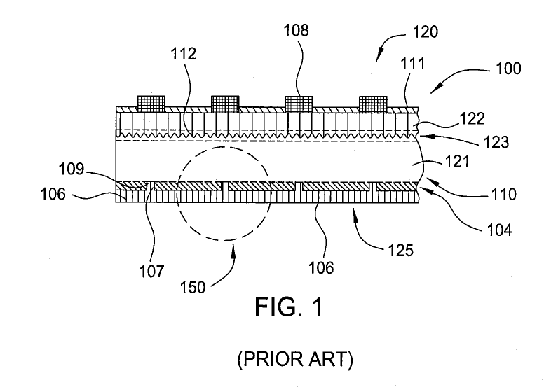

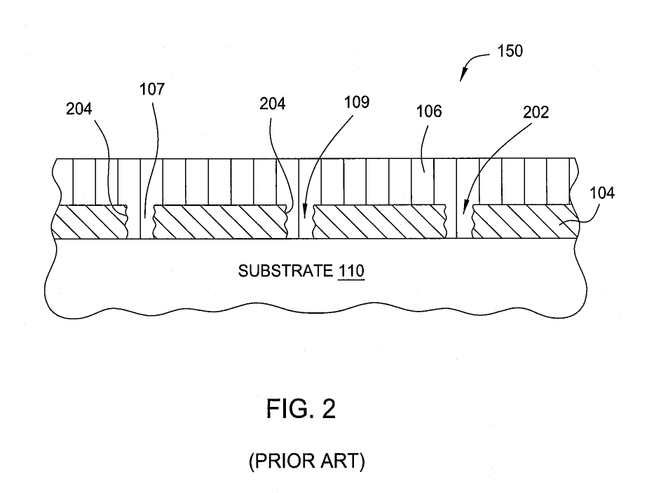

This radiation beam from the focusing optical module 310 is then focused by at least one lens 320 into a line of radiation 312 directed at a material layer, such as the passivation layer 352 similar to the passivation layer 104 depicted in FIG. 1, disposed on the substrate 350. The radiation 312 is controlled to be scanned along on a surface of a material layer disposed on the substrate 350, such as the passivation layer 352 similar to the passivation layer 104 depicted in FIG. 1, to remove a portion of the passivation layer 352 to form openings therein. In one embodiment, the radiation 312 may scan around the surface of the passivation layer 352 disposed on the substrate 350 as many times as needed until the openings are formed in the passivation layer 352 as desired.

Lens 320 may be any suitable lens, or series of lenses, capable of focusing radiation into a line or spot. In one embodiment, lens 320 is a cylindrical lens. Alternatively, lens 320 may be one or more concave lenses, convex lenses, plane mirrors, concave mirrors, convex mirrors, refractive lenses, diffractive lenses, Fresnel lenses, gradient index lenses, or the like.

The laser patterning apparatus 300 may include the translation mechanism 316 configured to translate the stage 302 and the line of radiation 312 relative to one another. In one embodiment, the translation mechanism 316 is coupled to the stage 302 that is adapted to move the stage 302 relative to the laser radiation source 308 and/or the focusing optical module 310. In another embodiment, the translation mechanism 316 is coupled to the laser radiation source 308 and/or the focusing optical module 310 to move the laser radiation source 308, the focusing optical module 310, and/or an actuated mirror (not shown) to cause the beam of energy to move relative to the substrate 350 that is disposed on the stage 302. In yet another embodiment, the translation mechanism 316 moves both the laser radiation source 308 and/or the focusing optical module 310, and the stage 302. Any suitable translation mechanism may be used, such as a conveyor system, rack and pinion system, or an x/y actuator, a robot, or other suitable mechanical or electro-mechanical mechanism. Alternatively, the stage 302 may be configured to be stationary, while a plurality of galvanometric head (not shown) may be disposed around the substrate edge to direct radiation from the laser radiation source 308 to the substrate edge as needed.

The translation mechanism 316 may be coupled to a controller 314 to control the scan speed at which the stage 302 and the line of radiation 312 move relative to one another. In general, the stage 302 and the line of radiation 312 are moved relative to one another so that the delivered energy translates to desired one regions of the passivation layer 352 formed on the substrate 350 so that other regions of the passivation layer 352 formed on the substrate 350 are not damaged. In one embodiment, the translation mechanism 316 moves at a constant speed. In another embodiment, the translation of the stage 302 and movement of the line of radiation 312 follow different paths that are controlled by the controller 314.

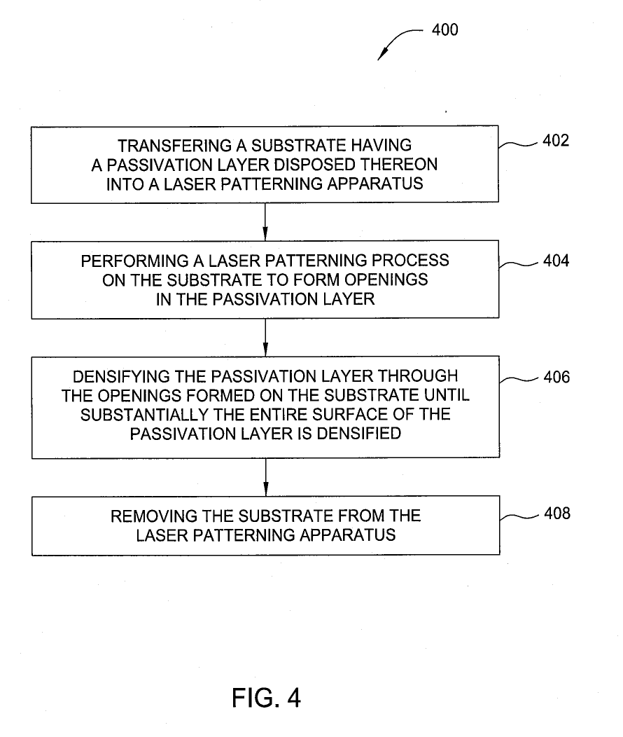

FIG. 4 depicts a flow diagram of a process 400 to perform a laser patterning process on a passivation layer disposed on a substrate for forming a solar cell device according to embodiments of the invention. The laser patterning process may be performed by a laser patterning apparatus, such as the laser patterning apparatus 300 described above with referenced to FIG. 3. It is contemplated that the process 400 may be adapted to be performed in any other suitable processing reactors, including those available from other manufacturers, to form openings in a material layer disposed on a substrate. It should be noted that the number and sequence of steps illustrated in FIG. 4 are not intended to limiting as to the scope of the invention described herein, since one or more steps can be added, deleted and/or reordered were appropriate without deviating from the basic scope of the invention described herein.

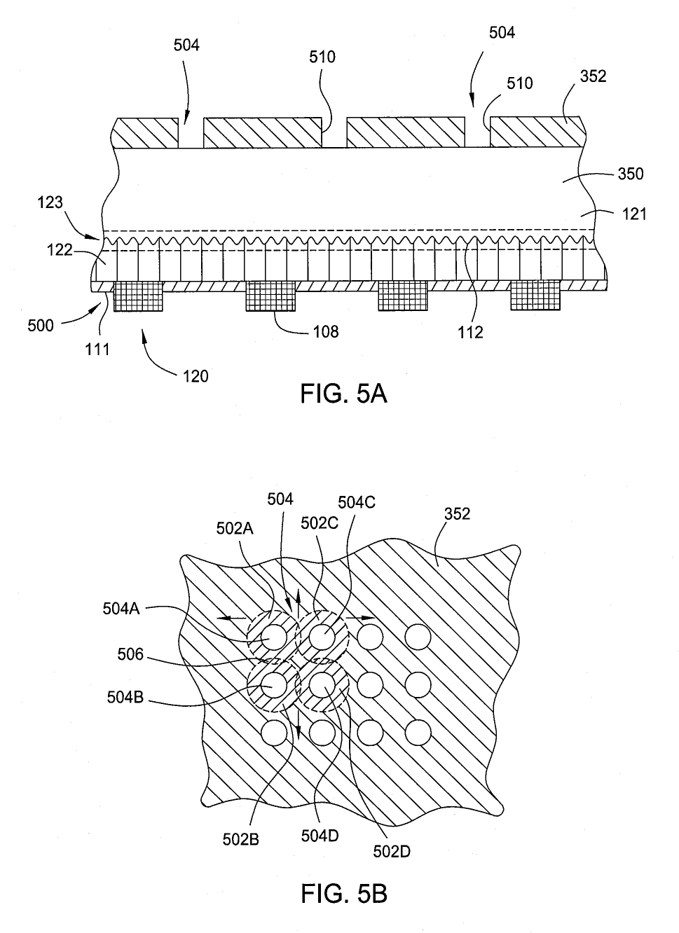

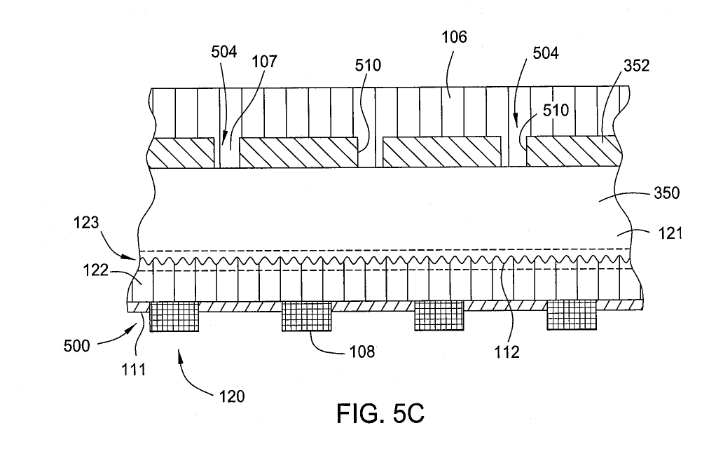

The process 400 begins at step 402 by transferring the substrate 350 having the passivation layer 352, similar to the passivation layer 104 formed on the substrate 110 depicted above with referenced to FIG. 1, into a laser patterning apparatus, such as the laser patterning apparatus 300 depicted in FIG. 3 configured to form the openings 504 and later filled openings 504 with a back metal contact, as depicted in FIG. 5A. It is noted that the substrate 350 depicted in FIG. 5A is flipped over and configured to be up side down to expose the passivation layer 352 disposed on the back surface 354 for the laser patterning process for ease of explanation of the laser patterning process performed on the passivation layer 352.

As briefly discussed above, the substrate 350 may be a crystalline silicon type solar cell substrate 350 having the textured surface 112. The substrate 350 includes the p-type base region 121, the n-type emitter region 122, and the p-n junction region 123 disposed therebetween. The n-type emitter region 122 may be formed by doping a deposited semiconductor layer with certain types of elements (e.g., phosphorus (P), arsenic (As), or antimony (Sb)) in order to increase the number of negative charge carriers, i.e., electrons. In one embodiment, the n-type emitter region 122 is formed by use of an amorphous, microcrystalline, nanocrystalline, or polycrystalline CVD deposition process that contains a dopant gas, such as a phosphorus containing gas (e.g., PH₃). The passivation layer 352 is disposed on the p-type base region 121 on the back surface 354 of the solar cell 500. The passivation layer 352 may be a dielectric layer providing good interface properties that reduce the recombination of the electrons and holes, drives and/or diffuses electrons and charge carriers back to the junction region 123. In one embodiment, the passivation layer 352 may be fabricated from a dielectric material selected from a group consisting of silicon nitride (Si₃N₄), silicon nitride hydride (SixNy:H), silicon oxide, silicon oxynitride, a composite film of silicon oxide and silicon nitride, an aluminum oxide layer, a tantalum oxide layer, a titanium oxide layer, or any other suitable materials. In an exemplary embodiment, the passivation layer 352 utilized herein is an aluminum oxide layer (Al₂O₃). The aluminum oxide layer (Al₂O₃) may be formed by any suitable deposition techniques, such as atomic layer deposition (ALD) process, plasma enhanced chemical vapor deposition (PECVD) process, metal-organic chemical vapor deposition (MOCVD), sputter process or the like. In an exemplary embodiment, the passivation layer 352 is an aluminum oxide layer (Al₂O₃) is formed by an ALD process having a thickness between about 5 nm and about 120 nm. The passivation layer 352 is formed on the back surface 354 of the substrate 350 readily to form openings 504 therein by the process 400 that later allows fingers of the back metal contact to be later filled therein. The detail of the process 400 with regard to forming openings 504 in the passivation layer 352 will be described below.

The front contacts 108 are generally configured as widely-spaced thin metal lines, or fingers, that supply current to larger buss bars transversely oriented relative to the fingers. In one embodiment, the front contacts 108 is fabricated from a metal selected from a group consisting of aluminum (Al), silver (Ag), tin (Sn), cobalt (Co), nickel (Ni), zinc (Zn), lead (Pb), tungsten (W), titanium (Ti) and/or tantalum (Ta), nickel vanadium (NiV) or other similar materials. In one embodiment, portion of the front contacts 108 disposed on the surfaces 120 of the substrate 350 using a screen printing process performed in a screen printing tool, which is available from Baccini S.p.A, a subsidiary of Applied Materials, Inc. Furthermore, the solar cell 500 may be covered with a thin layer of a dielectric material 111 to act as an anti-reflection coating (ARC) layer that minimizes light reflection from the top surface 120 of the solar cell 500. In one example, the dielectric material layer 111 functioning as the anti-reflection coating (ARC) layer may be selected from a group consisting of silicon nitride (Si₃N₄), silicon nitride hydride (SixNy:H), silicon oxide, silicon oxynitride, a composite film of silicon oxide and silicon nitride, and the like.

At step 404, a laser patterning process is performed on the passivation layer 352 disposed the substrate 350 on the stage 302 disposed in the apparatus 300, as shown in the exemplary embodiment depicted in FIG. 3. The substrate 350 depicted in FIG. 3 is flipped over and configured to be up side down to expose the passivation layer 352 disposed on the back surface 354 for the laser patterning process. In one embodiment, the laser patterning process is performed by applying a series of laser pulses onto the passivation layer 352 to form the openings 504 (shown as 504a, 504b, 504c, 504d) in the passivation layer 352, as shown in a top view of the passivation layer 352 depicted in FIG. 5B. The bursts of laser pulse may have a laser of wavelength between about 180 nm and about 1064 nm, such as about 355 nm. Each pulse is focused or imaged to spot at certain regions of the passivation layer 352 to form openings 504 therein. Each pulse is focused and is directed so that the first spot is at the start position of an opening to be formed in the passivation layer 352. Each opening 504 (shown as 504a, 504b, 504c, 504d in FIG. 5B) as formed in the passivation layer 352 may have equal distance to each other. Alternatively, each opening 504 may be configured to have different distances from one another, or may be spaced/located in any manner as needed.

In one embodiment, the spot size of the laser pulse is controlled at between about 5 μm and about 100 μm, such as about 25 μm. The spot size of the laser pulse may be configured in a manner to form openings 504 in the passivation layer 352 with desired dimension and geometries. In one embodiment, a spot size of a laser pulse about 25 μm may form an opening 504 in the passivation layer 352 with a diameter about 30 μm.

The laser pulse may have energy density (e.g., fluence) between about 15 microJoules per square centimeter (mJ/cm²) and about 50 microJoules per square centimeter (mJ/cm²), such as about 30 microJoules per square centimeter (mJ/cm²) at a frequency between about 30 kHz and about 70 kHz. Each laser pulse length is configured to be about 80 nanoseconds. The laser pulse is continuously pulsed until the openings 504 are formed in the passivation layer 352 exposing the underlying substrate 350. In one embodiment, the laser may be continuously pulsed for between about 500 picoseconds and about 80 nanoseconds, such as about 50 nanoseconds. After a first opening 504a, for example, is formed in a first position defined in the passivation layer 352, a second opening 504b is then be consecutively formed by moving the laser pulse to direct to a second location where the second opening 504b desired to be formed in the passivation layer 352 to continue performing the laser patterning process until a desired number of the openings 504, including openings 504c, 504d, are formed in the passivation layer 352. In one embodiment, the total opening areas created by the openings 504 formed in the passivation layer 352 is about 4 percent of the area of the substantially entire passivation layer 352.

During the laser patterning process, the substrate 350 may be heated by the laser energy provided to the substrate 350. In one embodiment, during the laser patterning process, the substrate 350 may locally teach a temperature between about 450 degrees Celsius and about 1000 degrees Celsius.

At step 406, after the openings 504 (shown as 504a, 504b, 504c, 504d in FIG. 5B) are formed in the passivation layer 352, the laser pulse may be continuously applied to densify adjacent areas 502a, 502b, 502c, 502d formed around the openings 504 in the passivation layer 352. As depicted in the top view of FIG. 5B, after the openings 504a, 504b, 504c, 504d are formed in the passivation layer 352, the laser pulses continuously applied to the passivation layer 352 may continue providing heat energy to the film layers around the openings 504 formed in the passivation layer 352. For example, when laser pulses are continuously applied to the first opening 504a formed in the passivation layer 352, the area 502a (shown in a dotted circle around the opening 504a) adjacent to the circumscribing opening 504a may be continuously thermally laser treated, thereby resulting the film layers in the area 502a becoming densified. The excess laser energy applied after the openings 504 are formed may assist driving out moisture and also repairing dangling bonds in the area 502 of the passivation layer 352 created while forming the openings 504a. The densified and/or repaired film layer in the area 502a of the passivation layer 352 thus provide a good interface between the passivation layer 352 and the back metal contact 106 (e.g., fingers 107 of the back metal contact 106 which will be later filled and disposed into the openings 504 formed in the passivation layer 352, as shown in FIG. 5C), thereby preventing the back metal contact 106 leaking or diffusing into the area 502a in the passivation layer 352, creating undesired defects. When repairing the area 502a of the passivation layer 352 circumscribing the openings 504a, micro-pits, micro-cracks, or other undesired defects may be closed up or melted together, thereby assisting creating a robust and strong interface in the openings 504 that allow the back metal contact 106 later disposed therein being retained in the openings 504 without attacking the sidewall of the openings 504.

In one embodiment, the laser pulse may be continuously or non-continuously (ceased for a predetermined period as needed) applied to the substrate 350 for between 15 picoseconds and about 100 nanoseconds after the openings 504 are formed in the passivation layer 352. In another embodiment, the total process time, including forming the openings 504 in the passivation layer 352 at step 404 and the continuous laser pulses applied at step 406, may be performed between about 15 picoseconds and about 100 nanoseconds. In yet another embodiment, the laser pulses may be ceased to apply for a predetermined period between performing step 404 and 406 for between about 90 nanoseconds and about 0.5 seconds as needed for refocusing or realigning. It is noted that the laser energy as applied to the substrate 350 may be configured the same or varied as needed to complete the densifying process.

The densifying process may be performed until the areas 502a, 502b, 502c, 502d around the openings 504a, 504b, 504c, 504d are densified. The desified areas 502a, 502b, 502c, 502d may each have at least a partially overlapped area 506 so as to ensure substantially the entire passivation layer 352 remaining on the substrate 350 after the laser patterning process is substantially and completely densified. In one embodiment, the overlapped area 506 may have a minimum area about two percent for each of the desified areas 502a, 502b, 502c, 502d.

At step 408, after the densifying process, the substrate 350 can then be removed from the laser patterning apparatus. Subsequently, a plurality of fingers 107 and the back metal contact 106 can then be formed and filled in the openings 504 formed in the passivation layer 352, as shown in FIG. 5C. The plurality of fingers 107 and the back metal contact 106 may be formed within the passivation layer 352 that are electrically connected to the back metal contact 106 to facilitate electrical flow between the back contact 106 and the p-type base region 121. In one embodiment, the back contact 106 disposed on the back surface 354 of the substrate 350 using a screen printing process performed in a screen printing tool, which is available from Baccini S.p.A, a subsidiary of Applied Materials, Inc. In one embodiment, the back contact 106 is heated in an oven to cause the deposited material to densify and form a desired electrical contact with the substrate back 354. It is noted other processes, such as a cleaning process, a rinse process, or other suitable process may be performed after the densifying process at step 406, before the metal back deposition process

Thus, the present application provides methods for forming openings in a passivation layer on a surface of a solar cell. The methods advantageously form openings in a passivation layer with strong and robust interface where the back metal contact can be formed and contacted therewith. Strong and robust interface formed between the passivation layer and the back metal contact may assist enhancing photocurrent generated in the solar junction cell, thereby improving the overall solar cell conversion efficiency and electrical performance.

While the foregoing is directed to embodiments of the present invention, other and further embodiments of the invention may be devised without departing from the basic scope thereof, and the scope thereof is determined by the claims that follow.

What is claimed is:

1. A method of forming an opening in a passivation layer on a solar cell substrate, comprising:
forming a passivation layer on a back surface of a substrate, the substrate having a first type of doping atom on the back surface of the substrate and a second type of doping atom on a front surface of the substrate; and
providing a series of laser pulses to the passivation layer for between about 500 picoseconds and about 80 nanoseconds to form openings in the passivation layer.

2. The method of claim 1, wherein the substrate comprises a p-type substrate and the first type of doping atom is boron.

3. The method of claim 1, wherein the passivation layer is an aluminum oxide layer.

4. The method of claim 1, further comprising:
providing laser pulses to an area adjacent to the openings in the passivation layer to densify the area after the openings have been formed.

5. The method of claim 4, further comprising:
providing laser pulses to densify the area around the openings after the openings have been formed for a period of between about 15 picoseconds and about 100 nanoseconds.

6. The method of claim 1, wherein providing the series of laser pulses to the passivation layer further comprises:
pulsing laser energy between about 15 microJoules per square centimeter (mJ/cm²) and about 50 microJoules per square centimeter (mJ/cm²) to the passivation layer.

7. The method of claim 1, wherein providing the series of laser pulses to the passivation layer further comprises:
providing the laser pulses at a wavelength between about 180 nm and about 1064 nm.

8. The method of claim 1, wherein providing the series of laser pulses to the passivation layer further comprises:
heating the substrate to a temperature between about 450 degrees Celsius and about 1000 degrees Celsius.

9. The method of claim 4, further comprising:
forming a back metal layer in the openings formed in the passivation layer, wherein the back metal is selected from a group consisting of aluminum (Al), silver (Ag), tin (Sn), cobalt (Co), nickel (Ni), zinc (Zn), lead (Pb), tungsten (W), titanium (Ti) and/or tantalum (Ta) and nickel vanadium (NiV).

10. The method of claim 1, wherein the openings formed in the passivation layer create an opening area about 4 percent to an area of the passivation layer formed on the substrate back surface.

11. A method of forming an opening in a passivation layer on a solar cell substrate, comprising:
forming a passivation layer on a back surface of a substrate, the substrate having a first type of doping atom on the back surface of the substrate and a second type of doping atom on a front surface of the substrate;
performing a laser drilling process to form openings in the passivation layer, wherein a series of laser pulses is applied to the passivation layer for between about 500 picoseconds and about 80 nanoseconds and laser energy is pulsed between about 15 microJoules per square centimeter (mJ/cm²) and about 50 microJoules per square centimeter (mJ/cm²) during the process.

12. The method of claim 11, wherein the substrate comprises a p-type substrate and the first type of doping atom is boron.

13. The method of claim 11, wherein the passivation layer is an aluminum oxide layer or a composite layer including a silicon oxide layer and a silicon nitride layer.

14. The method of claim 11, further comprising:
providing laser pulses to an area formed adjacent to the openings in the passivation layer to densify the area after the openings have been formed.

15. The method of claim 14, further comprising:
providing laser pulses to densify the area around the openings after the openings have been formed for a period of between about 15 picoseconds and about 100 nanoseconds.

16. The method of claim 11, wherein providing the series of laser pulses to the passivation layer further comprises:
providing the laser pulses at a wavelength between about 180 nm and about 1064 nm.

17. The method of claim 14, further comprising:
depositing a back metal layer in the openings formed in the passivation layer, wherein the back metal is selected from a group consisting of aluminum (Al), silver (Ag), tin (Sn), cobalt (Co), nickel (Ni), zinc (Zn), lead (Pb), tungsten (W), titanium (Ti) and/or tantalum (Ta) and nickel vanadium (NiV).

18. The method of claim 1, wherein the openings formed in the passivation layer create an opening area about 4 percent to an area of the passivation layer formed on the substrate back surface.

19. A method of forming an opening in a passivation layer on a solar cell substrate, comprising:
forming a passivation layer on a back surface of a substrate, the substrate having a first type of doping atom on the back surface of the substrate and a second type of doping atom on a front surface of the substrate;
patterning the passivation layer to form openings in the passivation layer by a first laser process for a first period of time; and
densifying film layers adjacent to the openings formed in the passivation layer by a second laser process for a second period of time.

20. The method of claim 19, wherein the first laser process and the second laser process are performed sequentially without interruption, and the first period time is between about 500 picoseconds and about 80 nanoseconds and the second period time is between about 15 picoseconds and about 100 nanoseconds.
